(19) United States
(12) Patent Application Publication
(10) Pub. No.: US 2017/0019212 A1
(43) Pub. Date: Jan. 19, 2017

(54) METHOD AND DEVICE FOR DECODING LOW-DENSITY PARITY CHECK CODE FOR FORWARD ERROR CORRECTION IN WIRELESS COMMUNICATION SYSTEM

(71) Applicant: LG ELECTRONICS INC., Seoul (KR)

(72) Inventors: Kwangseok NOH, Seoul (KR); Genebeck HAHN, Seoul (KR); Jinmin KIM, Seoul (KR); Kukheon CHOI, Seoul (KR); Jaehoon CHUNG, Seoul (KR); Eunjong LEE, Seoul (KR)

(73) Assignee: LG ELECTRONICS INC., Seoul (KR)

(21) Appl. No.: 15/124,524

(22) PCT Filed: Aug. 6, 2014
(86) PCT No.: PCT/KR2014/007270

§ 371 Date: Sep. 8, 2016

Related U.S. Application Data
(60) Provisional application No. 61/952,138, filed on Mar. 13, 2014.

(51) Int. Cl. H04L 1/00; H03M 13/11

(52) U.S. Cl. CPC H04L 1/0052; H04L 1/0057; H03M 13/1111

(57) ABSTRACT

A method for decoding an LDPC code for a forward error correction by a reception terminal of a wireless communication system according to an embodiment o the present invention comprises, in a bipartite graph including nodes that are differentiated into received nodes to which received packets are mapped and restoration nodes connected via edges to the received nodes, he steps of: obtaining first restoration packets corresponding to the restoration nodes using edges on a first packet passing path; determining error packet candidates to be excluded from the received packets when an error is detected in the first restoration packets; and obtaining second restoration packets from the bipartite graph from which the determined error packet candidates are excluded, wherein the step of obtaining the second restoration packets obtains the second restoration packets through the edges of a second packet passing path except for the edges of the received nodes to which the error packet candidates are mapped.

### TECHNICAL FIELD

The present invention relates to a method and apparatus for decoding a low density parity check (LDPC) using a Message Passing (MP) algorithm such that a reception (Rx) terminal of a wireless communication system performs forward error correction (FEC).

### BACKGROUND ART

Error correction for use in a wireless communication system is generally classified into automatic repeat request (ARQ) and forward error correction (FEC), and a hybrid ARQ is a combination of ARQ and FEC.

In accordance with ARQ, if a reception terminal detects an error in a reception packet, the reception terminal explicitly transmits a negative acknowledgement (NACK) message to request retransmission from the transmission terminal. A transmission terminal performs packet retransmission even when the explicit ACK/NACK messages are not received from the reception terminal within a predetermined time. In order to allow the reception terminal to determine the presence or absence of an error in the reception packet, a checksum or cyclic redundancy check (CRC) may be attached to the packet.

In accordance with FEC, the reception terminal may autonomously perform error correction when detecting the error in the reception packet. Since the reception terminal can directly correct the error of the reception packet, the reception terminal may not request retransmission from the transmission terminal. In order to allow the reception terminal to determine the presence or absence of an error in the reception packet as well as to perform error correction, an error correction code (ECC) corresponding to a kind of redundancy may be attached to the packet. As representative examples of ECC generation codes using FEC, a Hamming code, a Bose-Chaudhuri-Hocquenghem (BCH) code, a Reed-Solomon (RS) code, and a low density parity check (LDPC) code, etc. may be used.

In 3GPP LTE, HARQ is used. In 3GPP MBMS (Multimedia Broadcast/Multicast Service), Application Layer Forward Error Correction (AL-FEC) is used. AL-FEC is an error correction method for an application layer, and the 3GPP MBMS protocol stack shown in FIG. 1 includes AL-FEC. FEC for a physical layer may determine ‘0’ or ‘1’ and perform correction on the basis of a probability. In contrast, FEC in the application layer may already be determined to be ‘0’ or ‘1’, or may perform error correction for a blank (or empty) part caused by loss or damage. Accordingly, FEC for the physical layer and FEC for the application layer can be easily distinguished from each other.

In 3GPP MBMS, AL-FEC may use Raptor codes based on LDPC codes. AL-FEC of the 3GPP MBMS system may decode the packet having passed through a UDP protocol. The decoding method of the LDPC codes is broadly classified into a Maximum Likelihood (ML) algorithm and a Message Passing (MP) algorithm.

### DISCLOSURE

### Technical Problem

An object of the present invention is to provide a method for omitting a checksum of at least some packets in a transmission (Tx) layer so as to transmit a packet without retransmission, and a method and apparatus for decoding an LDPC code configured to perform forward error correction (FEC) of a packet error generated by such checksum omission in the application layer.

It will be appreciated by persons skilled in the art that the objects that could be achieved with the present invention are not limited to what has been particularly described hereinabove and the above and other objects that the present invention could achieve will be more clearly understood from the following detailed description.

### Technical Solution

The object of the present invention can be achieved by providing a method for decoding a low density parity check (LDPC) code for forward error correction (FEC) by a reception terminal of a wireless communication system including: in a bipartite graph including a plurality of nodes halved into reception nodes mapped to reception packets and reconstructed nodes connected to the reception nodes through edges, acquiring first reconstructed packets corresponding to the reconstructed nodes by using edges of a first packet transmission path; if an error is detected in the first reconstructed packets, determining a candidate of an error packet to be excluded from the reception packet; and acquiring second reconstructed packets from the bipartite graph from which the determined error packet candidate is excluded, wherein the acquiring the second reconstructed packets includes acquiring the second reconstructed packets through edges of a second packet transmission path from which an edge of a reception node mapped to the error packet candidate is excluded.

In another aspect of the present invention, an apparatus for decoding a low density parity check (LDPC) code for forward error correction (FEC) of a wireless communication system includes: a receiver configured to receive encoded reception packets; and a processor, in a bipartite graph including a plurality of nodes halved into reception nodes mapped to reception packets and reconstructed nodes connected to the reception nodes through edges, configured to acquire first reconstructed packets corresponding to the reconstructed nodes by using edges of a first packet transmission path, if an error is detected in the first reconstructed packets, to determine a candidate of an error packet to be excluded from the reception packet, and to acquire second reconstructed packets from the bipartite graph from which the determined error packet candidate is excluded, wherein the processor is configured to acquire the second reconstructed packets through edges of a second packet transmission path from which an edge of a reception node mapped to the error packet candidate is excluded.

### Advantageous Effects

As is apparent from the above description, the wireless communication system according to the embodiments can reduce an End to End delay caused by retransmission because a checksum of at least some packets is omitted from a transmission (Tx) layer. Packet error caused by such checksum omission is corrected through forward error correction (FEC) in the application layer, resulting in improvement of Quality of Service (QoS).

It will be appreciated by persons skilled in the art that the effects that can be achieved with the present invention are not limited to what has been particularly described hereinabove and other advantages of the present invention will be more clearly understood from the following detailed description taken in conjunction with the accompanying drawings.

### DESCRIPTION OF DRAWINGS

FIG. 1 is a conceptual diagram illustrating a 3GPP MBMS protocol stack.

FIG. 2 is a conceptual diagram illustrating a wireless communication system according to one embodiment of the present invention.

FIG. 3 is a conceptual diagram illustrating UDP and UDP-Lite acting as exemplary protocols of the protocol applicable to a transmission layer of a wireless communication system.

FIG. 4 is a conceptual diagram illustrating an encoding process based on a Message Passing (MP) algorithm.

FIGS. 5A and 5D are conceptual diagrams illustrating the decoding process based on the MP algorithm.

FIGS. 5B and 5E are conceptual diagrams illustrating error propagation for the decoding process based on the MP algorithm.

FIGS. 5C and 5F are conceptual diagrams illustrating a packet transmission path for use in the decoding process based on the MP algorithm.

FIGS. 6 to 10 are conceptual diagrams illustrating the decoding processes according to embodiments of the present invention.

FIG. 11 is a flowchart illustrating a decoding method according to an embodiment of the present invention.

FIG. 12 is a block diagram illustrating an apparatus for performing the decoding method according to an embodiment of the present invention.

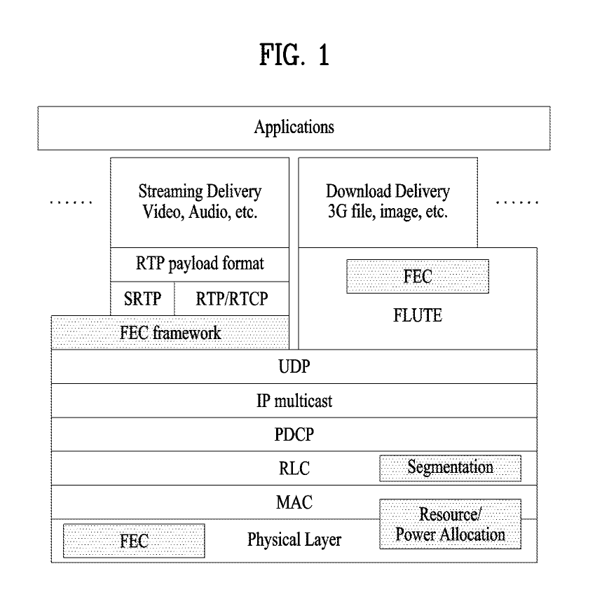

### BEST MODE

Reference will now be made in detail to the preferred embodiments of the present invention, examples of which are illustrated in the accompanying drawings. The detailed description, which will be given below with reference to the accompanying drawings, is intended to explain exemplary embodiments of the present invention, rather than to show the only embodiments that can be implemented according to the present invention. The following detailed description includes specific details in order to provide a thorough understanding of the present invention. However, it will be apparent to those skilled in the art that the present invention may be practiced without such specific details.

In some cases, to prevent the concept of the present invention from being ambiguous, structures and apparatuses of the known art will be omitted, or will be shown in the form of a block diagram based on main functions of each structure and apparatus. Also, wherever possible, the same reference numbers will be used throughout the drawings and the specification to refer to the same or like parts. Specific terminologies hereinafter used in the embodiments of the present invention are provided to assist understanding of the present invention, and various modifications may be made in the specific terminologies within the range that they do not depart from technical spirits of the present invention.

The term ‘LDPC code’ may include a narrow-sense LDPC code and LDPC-based codes each employing a generation matrix. For example, the term ‘LDPC code’ may include the Raptor code and the LT code. Therefore, the embodiments of the present invention can be applied to LDPC-based codes, each of which uses a generation matrix.

The following embodiments will disclose the encoding and decoding process of the LDPC code on the basis of the LDPC code generation matrix. In the case of FED in the physical layer, LDPC codes are mainly disclosed from the viewpoint of the decoder. In the case of FEC in the physical layer, LDPC codes are mainly disclosed for the viewpoint of the decoder. Therefore, LDPC code decoding is generally disclosed on the basis of the parity check matrix used in the decoder. However, in the case of FEC in the application layer, LDPC codes are disclosed from the viewpoint of the encoder. Therefore, the embodiments of the present invention have disclosed LDPC code decoding on the basis of the LDPC code generation matrix used in the encoder. The generation matrix and the parity check matrix may indicate the LDPC code structure for use in the Tx terminal and the Rx terminal. Whereas it is very easy to explain the decoder using the parity check matrix, it is very difficult to explain the encoder using the parity check matrix. In contrast, the LDPC code generation matrix can be easily explained using the encoder and the decoder, such that the embodiments of the present invention have been disclosed on the basis of the LDPC code generation matrix. However, the decoding process based on the parity check matrix is not excluded from the scope or spirit of the present invention. Therefore, the decoding methods based on the LDPC code generation matrix according to the present invention may also be replaced with other decoding methods based on the parity check matrix within the equivalent ranges of the present invention.

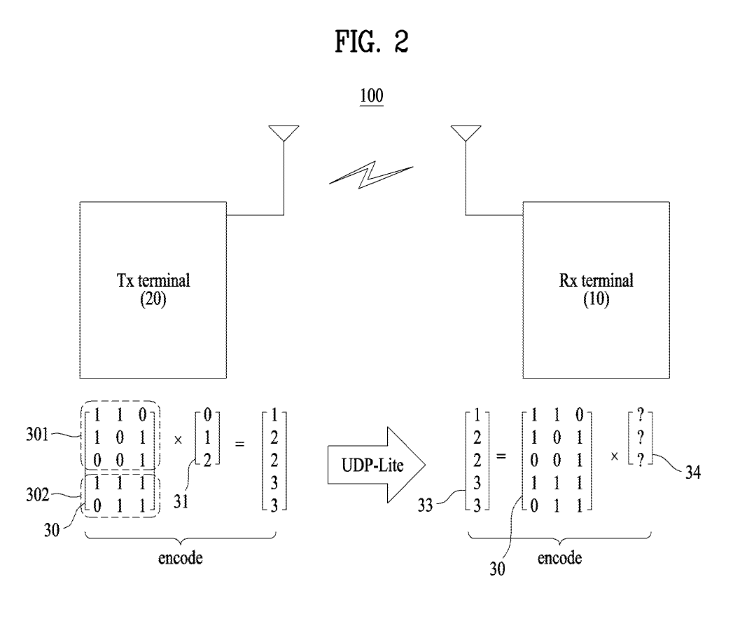

FIG. 2 is a conceptual diagram illustrating a wireless communication system according to one embodiment of the present invention.

Referring to FIG. 2, the wireless communication system 100 may include a transmission (Tx) terminal 20 and a reception (Rx) terminal 10. For example, the wireless communication system 100 may serve as a cellular system or a cellular network, and the following description will be given centering upon a wireless communication system serving as a 3GPP LTE or LTE-A system, but the present invention is not limited thereto and the remaining parts of the present invention other than unique characteristics of the 3GPP LTE or LTE-A system are applicable to the wireless communication system 100 acting as other cellular systems. The following embodiments of the present invention can be applied to a variety of wireless access technologies, for example, CDMA (Code Division Multiple Access), FDMA (Frequency Division Multiple Access), TDMA (Time Division Multiple Access), OFDMA (Orthogonal Frequency Division Multiple Access), SC-FDMA (Single Carrier Frequency Division Multiple Access), and the like. CDMA may be embodied through wireless (or radio) technology such as UTRA (Universal Terrestrial Radio Access) or CDMA2000. TDMA may be embodied through wireless (or radio) technology such as GSM (Global System for Mobile communication)/GPRS (General Packet Radio Service)/EDGE (Enhanced Data Rates for GSM Evolution). OFDMA may be embodied through wireless (or radio) technology such as Institute of Electrical and Electronics Engineers (IEEE) 802.11 (Wi-Fi), IEEE 802.16 (WiMAX), IEEE 802-20, and E-UTRA (Evolved UTRA). UTRA is a part of UMTS (Universal Mobile Telecommunications System). 3GPP (3rd Generation Partnership Project) LTE (long term evolution) is a part of E-UMTS (Evolved UMTS), which uses E-UTRA. 3GPP LTE employs OFDMA in downlink and employs SC-FDMA in uplink. LTE-Advanced (LTE-A) is an evolved version of 3GPP LTE. In addition, the wireless communication system 100 may be a wireless LAN (WLAN) or Wi-Fi system without being limited thereto.

In one embodiment, a receiver 10 or a transmitter 20 may refer to a mobile or fixed user equipment (UE), for example, a terminal, a user equipment (UE), a mobile station (MS), an Advanced Mobile Station (AMS), a station (STA), and the like. In another embodiment, a receiver 10 or the transmitter 20 may refer to an arbitrary node of a wireless communication system which communicates with the above terminal, and may include an eNode B (eNB), a base station (BS), a Node B (Node-B), an access point (AP), a relay, and the like.

The Tx terminal 20 may encode the input packet vector 31 using the LDPC code generation matrix 30, and thus generate a Tx packet vector 32. The Tx terminal 20 may transmit the Tx packet vector 32 to the Rx terminal 10.

The LDPC code generation matrix 30, the input packet vector 31, and the Tx packet vector 32 illustrated in FIG. 2 are disclosed only for illustrative purposes for convenience of description.

The input packet vector 31 may include K input packets. Here, K is an integer of 1 or greater, and denotes the size of the input packet vector 31, where the size K of the input packet vector 31 may be identical to the size of the reconstructed packet vector 34. Each input packet contained in the input packet vector 31 may include a plurality of bits, and may be changed in size in various ways. As can be seen from FIG. 2, the input packets ‘00’, ‘01’, ‘10’ in which k is set to 3 (k=3) and each input packet is expressed as 2 bits are contained in the input packet vector 31.

The LDPC code generation matrix 30 may include N row vectors and K column vectors. Here, N is an integer of K or higher, and N is the size of the Tx packet vector 34 and is identical in size to the Rx packet vector 33. The LDPC code generation matrix 30 may include a (k×k)-sized upper matrix 301 and an ((n−k)×k)-sized lower matrix 392. For convenience of description, the encoding result obtained by the upper matrix 301 will hereinafter be referred to as a data packet, and the encoding result obtained by the lower matrix 302 will hereinafter be referred to as a parity packet. The lower matrix 302 may add the parity packet to the Tx packet vector 32. In the ideal communication environment in which no errors occur, the lower matrix 302 may be omitted as necessary. However, in order to correct errors caused by a poor channel state, the parity packet caused by the lower matrix 302 is needed.

If the Tx terminal 20 encodes the input packet vector 31 including K input packets, the Tx packet vector 32 including N transmission (Tx) packets is output.

The Tx packet vector 32 transmitted from the Tx terminal 20 may be affected by RF-channel noise or the like. The Tx packet vector 32 affected by the RF channel will hereinafter be referred to as a reception (Rx) packet vector 33.

The Tx terminal 10 may acquire the reconstructed packet vector 34 by decoding the Rx packet vector 33. The LDPC code generation matrix 30 is needed to decode the Rx packet vector 33, such that the LDPC code generation matrix 30 may be prestored in the Rx terminal 10. A method for decoding the Rx packet vector using the LDPC code generation matrix 30 using the Rx terminal 10 is largely classified into a Maximum Likelihood (ML) algorithm and a Message Passing (MP) algorithm, and the embodiments of the present invention are based on the ML algorithm.

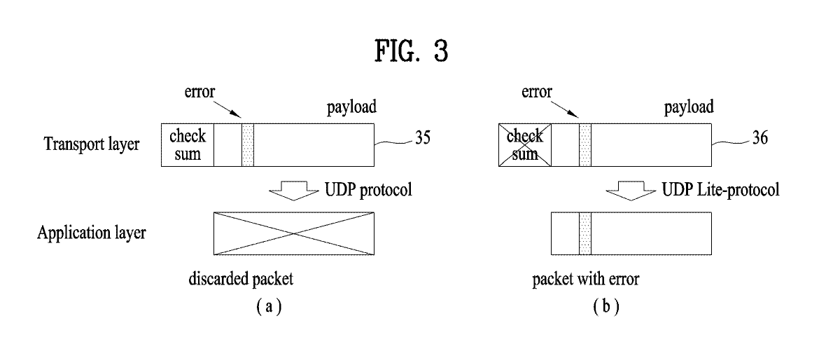

Meanwhile, the UDP or UDL-Lite protocol may be used in the transmission layer for packet transmission between the Tx terminal 20 and the Rx terminal 10. The UDP protocol and the UDP-Lite protocol will hereinafter be described with reference to FIG. 3.

Referring to FIG. 3(a), the reception packet 35 received by the UDP protocol may include a checksum. Errors generated in the transmission process may be detected using the checksum. The Rx packet 35 having such errors may be discarded.

Referring to FIG. 3(b), the UDP-Lite protocol may permit errors of payload of the Rx packet 36. In the case of using the UDP-Lite protocol, at least some packets may not use the checksum. That is, when using the UDP-Lite protocol, the checksum may be used in some packets, and the checksum may not be used in some other packets as necessary. In another embodiment, the checksum for the entire packets may be omitted. The reception (Rx) packet received through the UDP-Lite protocol does not have the checksum, such that the Rx packet is not discarded even when errors exist in the payload and the resultant Rx packet is transmitted to an upper layer.

Although the checksum error occurs, a method for using multimedia data may permit occurrence of some errors, without stopping display of screen images by discarding all the packets, such that noise may be displayed on the screen image even when checksum errors occur in the multimedia data. Therefore, the UDP-Lite protocol may be more appropriate for multimedia data transmission than the UDP protocol. Specifically, although there is a high possibility that a very small number of erroneous symbols occurs in each packet when using a very efficient error correction code in the physical layer, discarding of the entire packet according to the UDP protocol is far from efficient.

Meanwhile, the legacy AL-FEC designed considering the UDP protocol assumes that the Rx packet does not include errors. That is, since the legacy AL-FEC based on the UDP protocol does not have errors in the Rx packet, AL-FEC is very vulnerable to processing of the erroneous Rx packet. Specifically, a combination of the UDP-Lite protocol and the legacy AL-FEC may cause error propagation, such that serious performance deterioration occurs as compared to the other case in which AL-FEC is not used. Therefore, although the legacy AL-FEC process can be temporarily stopped to use the UDP-Lite protocol, it may be preferable that AL-FEC be improved to be more appropriate for the UDP-Lite protocol.

### A. MP Algorithm

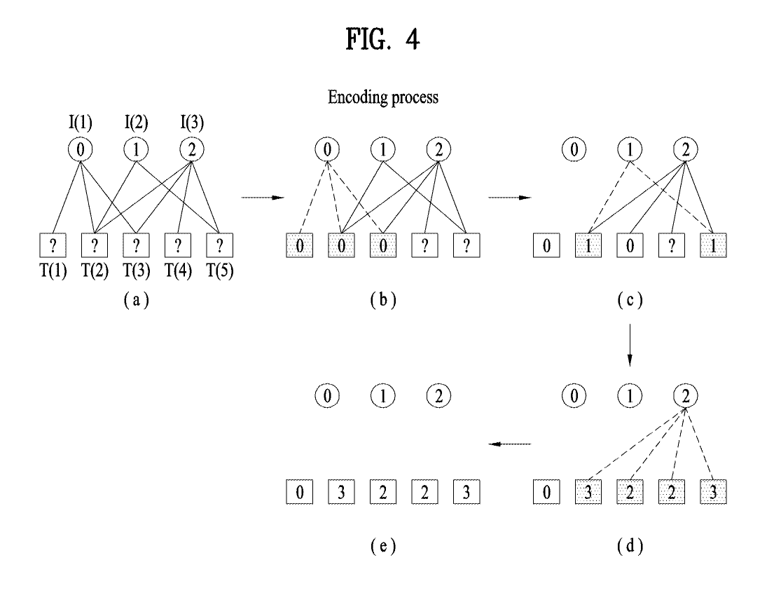

A method for allowing a transmission (Tx) terminal to encode input packets using a bipartite graph will hereinafter be described with reference to FIG. 4.

As can be seen from the bipartite graph of the Tx terminal, a plurality of nodes may be divided into two parts. i.e., input nodes and transmission (Tx) nodes. The input nodes are nodes mapped to input packets, and the Tx nodes are nodes mapped to Tx packets. Referring to FIG. 4(a), circular nodes respectively mapped to ‘0’, ‘1’, and ‘2’ are input nodes, and square nodes incapable of recognizing packets are Tx nodes. At least one edge is present between the input nodes and the Tx nodes. The edge may be a path for packet delivery between the input nodes and the Tx nodes. Since the packet delivery process is referred to as a Message Passing (MP) process, this algorithm is well known as the MP algorithm to those skilled in the art.

In the meantime, the bipartite graph may include K input nodes and N transmission (Tx) nodes. K is the number of input packets, and N is the number of Tx packets. K and N may also correspond to the number of column vectors and the number of row vectors in the LDPC code generation matrix, respectively. Each edge of the bipartite graph may correspond to elements each having ‘1’ in the LDPC code generation matrix. For example, if the element (i-th row, j-th column) of the LDPC code generation matrix is denoted by ‘1’, namely, if the element i-th row, j-th column) of the LDPC code generation matrix is denoted by ‘1’, the edge for interconnecting the i-th Tx node and the j-th input node is present in the bipartite graph. In association with the elements each having zero ‘0’ in the LDPC code generation matrix, the edge is not present in the bipartite graph. Therefore, the edges illustrated in the bipartite graph may indicate encoding characteristics of the LDPC code.

The same bipartite graph as that of the Tx terminal may be stored in the Rx terminal. Meanwhile, each input node contained in the bipartite graph of the Rx terminal will hereinafter be referred as a reconstructed node, and each Tx node contained in the bipartite graph of the Rx terminal will hereinafter be referred to as a reception (Rx) node. In the bipartite graph of the Tx terminal, I(n) may denote the n-th input node, and T(m) may denote the m-th Tx node. In the bipartite graph of the Rx terminal, D(n) may denote the n-th reconstructed node, R(m) may denote the m-th reception (Rx) node, and [symbol] is defined as a bitwise exclusive OR (XOR) operation. The number of edges connected to the Tx node is defined as the term “degree”, or the number of edges connected to the Rx node is defined as the term “degree”. For example, the degree of T(1) is set to 1 and the degree of T(2) is set to 3 as illustrated in FIG. 4(a). VI(n) is defined as a packet value mapped to I(n). VT(n) is defined as a packet value mapped to T(n). VD(n) is defined as a packet value mapped to D(n). VR(n) is defined as a packet value mapped to R(n). In the meantime, the Tx packets mapped to Tx nodes may be acquired through an XOR operation of the Rx packets mapped to the Rx nodes connected through the edge. For example, VT(1)=VI(1)=0, VT(2)=VI(1) [symbol] VI(2) [symbol] VI(3)=3, VT(3)=VI(1) [symbol] VI(3)=2, VT(4)=VI(3)=2, and VT(5)=VI(2) [symbol] VI(3)=3 may be acquired.

FIGS. 4(b) to 4(e) are conceptual diagrams illustrating the encoding process according to one embodiment of the present invention. Instead of using the concepts of FIGS. 4(b) to 4(e), the encoding process may also be implemented in various other ways. FIGS. 4(b) to 4(3) are conceptual diagrams illustrating that I(1) to I(3) are sequentially delivered to T(1) to T(5) through the edges.

A method for allowing the Rx terminal to decode the Rx packets using the bipartite graph. First, the Rx terminal may map the Rx packets to the respective Rx nodes.

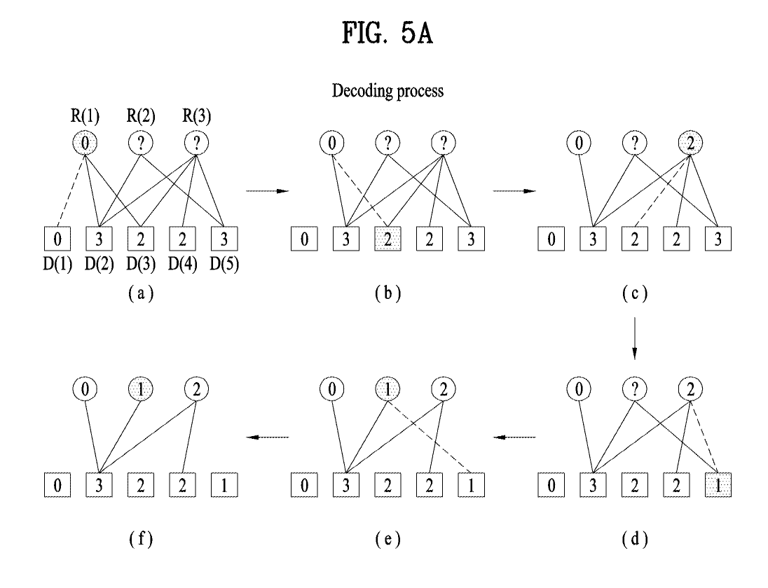

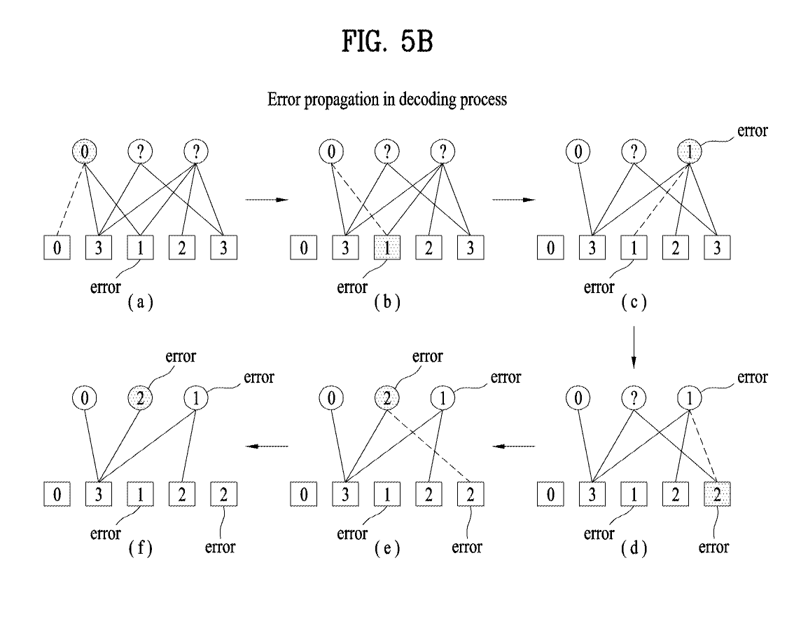

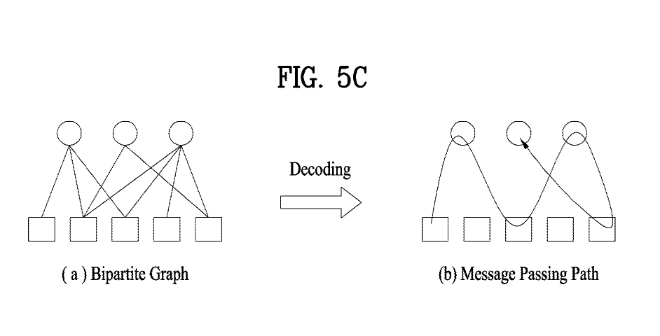

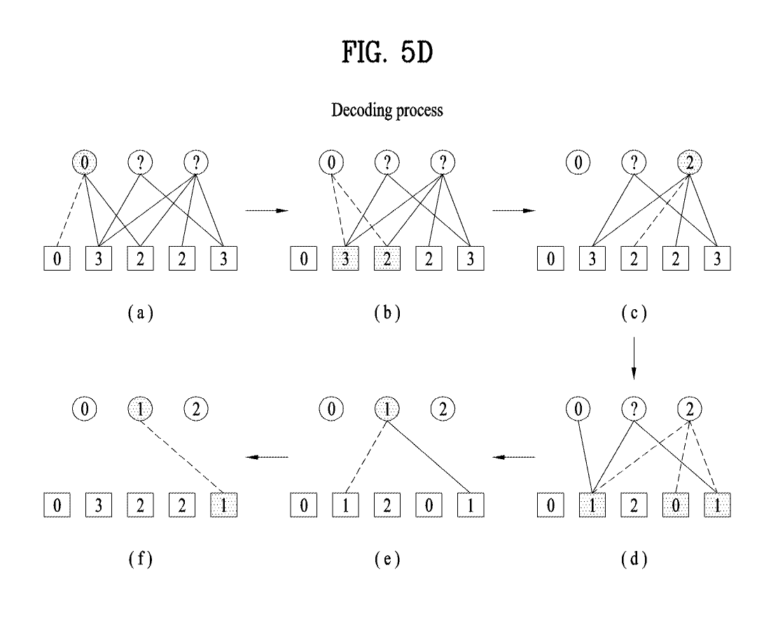

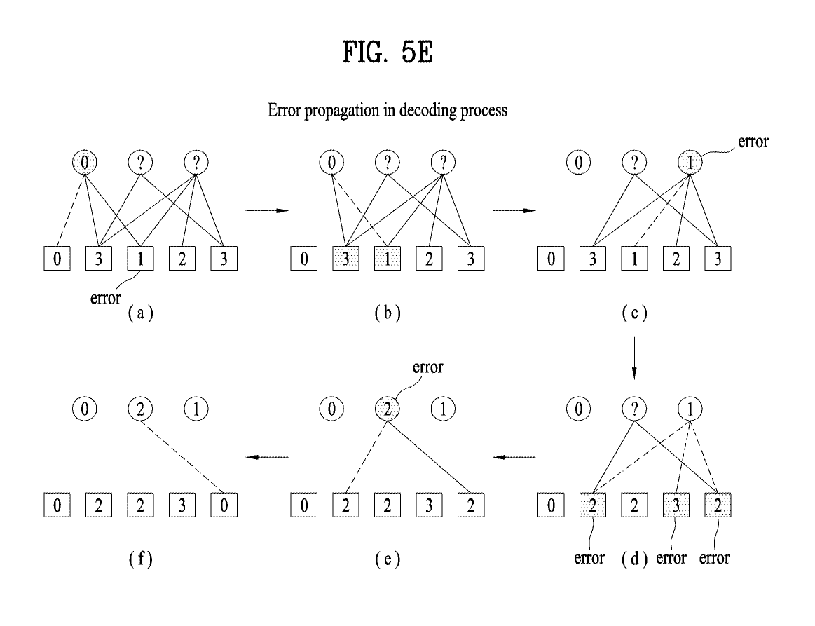

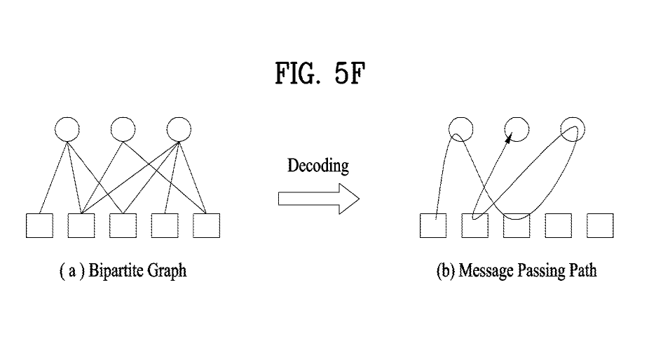

The Rx terminal may deliver the Rx packets of R(1) having ‘Degree=1’ from among the Rx nodes to D(1) through the edge as shown in FIG. 5A(a). The reconstructed node packet of D(1) is denoted by ‘0’. The edge used to deliver the Rx packet of R(1) is eliminated.

The Rx terminal may deliver the reconstructed packet to R(3) through the edge (See FIG. 5A(a)). For example, the Rx terminal may update R(d) by performing VR(3) [symbol] VD(1). The edge used to deliver the reconstructed packet of D(1) is eliminated.

Since the degree of the updated R(3) is denoted by ‘1’, the Rx terminal may transmit the Rx packet of R(3) to D(3) through the edge as shown in FIG. 5A(c). For example, the reconstructed packet of D(3) is denoted by ‘2’, and the edge used in deliver the Rx packet of R(3) is eliminated.

The Rx terminal may transmit the reconstructed packet of D(3) to R(5) through the edge as shown in FIG. 5A(a). For example, the Rx terminal may update R(5) through execution of VR(5) [symbol] VD(3). The edge used for transmission of the reconstructed packet of D(3) is eliminated.

Since the updated R(5) has the degree of 1, the Rx terminal may transmit the Rx packet of R(5) to D(2) through the edge as shown in FIG. 5A(e). For example, the reconstructed packet of D(2) is set to ‘1’. The edge used for transmission of the Rx packet of R(5) is eliminated.

If the reconstructed packets of all the reconstructed nodes are obtained, the decoding process is terminated when the Rx node having the degree of 1 is not present. As shown in FIG. 5A(f), since the reconstructed packets of all the reconstructed nodes are obtained, the decoding is terminated. In addition, the reconstructed packets are ‘0, ‘1’, and ‘2, and are identical to input packets.

FIG. 5D is a conceptual diagram illustrating the decoding process of the MP algorithm according to another embodiment. Differently from the embodiment of FIG. 5A, the plurality of Rx nodes can be simultaneously updated through the obtained reconstructed packets as shown in FIGS. 5D(b) and 5D(d). In addition, the decoding process of FIG. 5D is performed until all the edges are eliminated. However, it should be noted that the reconstructed packets based on the decoding processes of FIGS. 5A and 5D are identical to each other.

In FIGS. 5A and 5D, a packet transmission path (or a message passing path) including a plurality of edges needed to transmit the Rx packet or the reconstructed packet may be scheduled in different ways. In other words, a plurality of different packet transmission paths may also be present in the same bipartite graph. As the number of Rx nodes increases as compared to the increasing number of reconstructed nodes, the number of packet transmission paths also increases.

FIGS. 5C and 5F are conceptual diagrams illustrating a packet transmission path for use in the decoding process based on the MP algorithm. In FIG. 5C, the reconstructed packets are obtained using R(1), R(3), and R(5). In FIG. 5F, the reconstructed packets are obtained using R(1), R(2), and R(3).

### B. Error Propagation in MP Algorithm

FIGS. 5B and 5E are conceptual diagrams illustrating error propagation for the decoding process based on the MP algorithm.

Referring to FIG. 5B, although the R(3) reception (Rx) packet must be denoted by ‘2’, the R(3) reception packet ‘1’ has been received. If the checksum is not used, it is impossible to recognize the occurrence of errors in the Rx packet. Therefore, assuming that the R(3) reception (Rx) packet has no errors, the MP algorithm of FIG. 5B transmits the Rx packets and the reconstructed packets in the same manner as in FIG. 5A. The MP algorithm illustrated in FIG. 5E may also transmit the Rx packets and the reconstructed packets in the same manner as in FIG. 5D on the assumption that the R(3) Rx packet has no errors.

Errors generated in R(3) are propagated to D(3) of the process (c), R(5) of the process (d), and D(2) of the process (e) configured to directly/indirectly receive the Rx packet of R(3) as shown in FIG. 5B, such that the reconstructed packets ‘0’, ‘2’, and ‘1’ are acquired.

Similarly, errors generated in R(3) are propagated to D(3) of the process (c), R(2), R(4), and R(5) of the process (d), and D(2) of the process (e) configured to directly/indirectly receive the Rx packet of R(3) as shown in FIG. 5E, such that the reconstructed packets ‘0’, ‘2’, and ‘1’ are acquired.

Errors generated in any one Rx packet are propagated to another Rx node or the reconstructed node according to the packet transmission path. If the packet transmission path passes through the Rx packet having errors, errors may unavoidably occur in both each Rx node and each reconstructed node located at a subsequent packet transmission path.

### C. Protocol in Which Checksum is Not Used

As one example of the protocol used in the transmission (Tx) layer, if the UDP-Lite protocol does not use the checksum, one example of the decoding method according to the MP algorithm will hereinafter be given.

C-1) Error Correction (Validity Verification in the Reconstructed Packets)

A method for detecting errors in the reconstructed packets will hereinafter be described.

Referring to FIG. 5B, the checksum is not used, such that it is impossible for the Rx terminal to recognize the presence or absence of errors in the R(3) reception packet prior to decoding.

If the reconstructed packets of D(1) to D(3) are acquired as shown in FIG. 5B(f), the Rx terminal may recognize the presence or absence of errors in the reconstructed packets through the residual edges not eliminated. For example, the Rx terminal may determine whether VD(1) [symbol] VD(2) [symbol] VD(3)=VR(2) is satisfied and VD(3)=VR(2) is also satisfied in FIG. 5B(f). Because VD(3)≠VR(2) is achieved, the Rx terminal may recognize the presence of errors in the reconstructed packets. In other words, the Rx terminal may determine the presence or absence of errors in the reconstructed packets using the Rx packets VR(2) and VR(4) not located at the packet transmission path of FIG. 5C.

In this case, although the Rx terminal can recognize the presence of errors in the reconstructed packets, it is impossible for the Rx terminal to recognize which one of Rx packets includes an error. However, the Rx terminal can recognize that the Rx packet having errors is located at the packet transmission path of FIG. 5C.

Although the residual edges are not present as shown in FIG. 5E(f), it may be possible to recognize the presence or absence of errors in the reconstructed packets. For example, the Rx terminal determines whether the Rx nodes not located at the packet transmission path of FIG. 5F satisfy ‘VR(4)=VR(5)=0’. Since VR(4)≠0 is recognized, the Rx terminal can recognize the presence of errors in the reconstructed packets. In this case, although the Rx terminal can recognize the presence of errors in the reconstructed packets, it is impossible for the Rx terminal to recognize which one of Rx packets includes an error. However, the Rx terminal can recognize that the Rx packet having errors is located at the packet transmission path of FIG. 5F.

C-2) Error Correction

As described above, if errors are detected in the reconstructed packets, the Rx terminal may determine a candidate of at least one error packet from among the Rx packets.

The Rx terminal may exclude the determined candidate of the error packet from the Rx packet. The Rx terminal may exclude the Rx node mapped to the determined error packet candidate and the edges of the Rx node from the bipartite graph. Subsequently, the Rx terminal may re-acquire the reconstructed packets using the bipartite graph from which the error packet candidate is excluded. If no errors are present in the re-acquired reconstructed packet, decoding is successfully performed. If errors are also present in the re-acquired reconstructed packet, the error packet candidate is changed and decoding is re-performed.

The meaning that not only an error packet candidate but also the Rx node and edge mapped to the error packet candidate are excluded may conceptually include the operations for preventing the error packet candidate and the Rx node and edge mapped to the error packet candidate from being used in decoding. For example, a specific Rx node may be deleted or eliminated to exclude a specific Rx node. In contrast, the position of a specific Rx node is exchanged with the position of another Rx node, such that the specific reception node may be located at the outside of the packet transmission path or at the end of the packet transmission path.

The candidate of the error packet (i.e., the error packet candidate) may be determined from among the Rx packets used in the MP decoding process. For example, the error packet candidate may be determined to be any one of the Rx nodes located at the packet transmission path of FIG. 5C.

The degree of Rx nodes may be used to determine the error packet candidate. For example, the Rx packets of the Rx nodes may be determined to be the error packet candidate in ascending numerical order of the degrees.

In another embodiment, the Rx packets of the Rx nodes may be determined to be the error packet candidate in descending numerical order of the degrees. For example, R(3) or R(5) of FIG. 5C may be primarily determined to be the error packet candidate. A method for primarily determining the Rx packets of the Rx nodes having high degrees to be the error packet candidate will hereinafter be described.

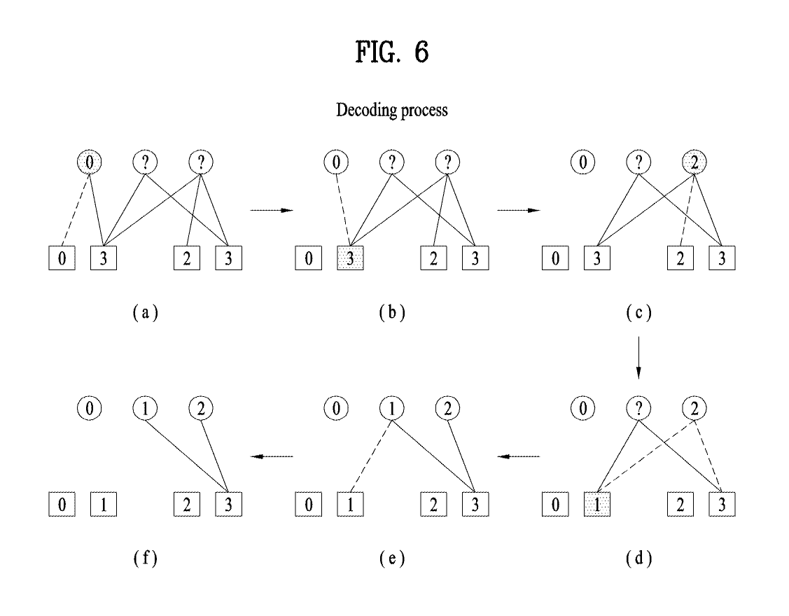

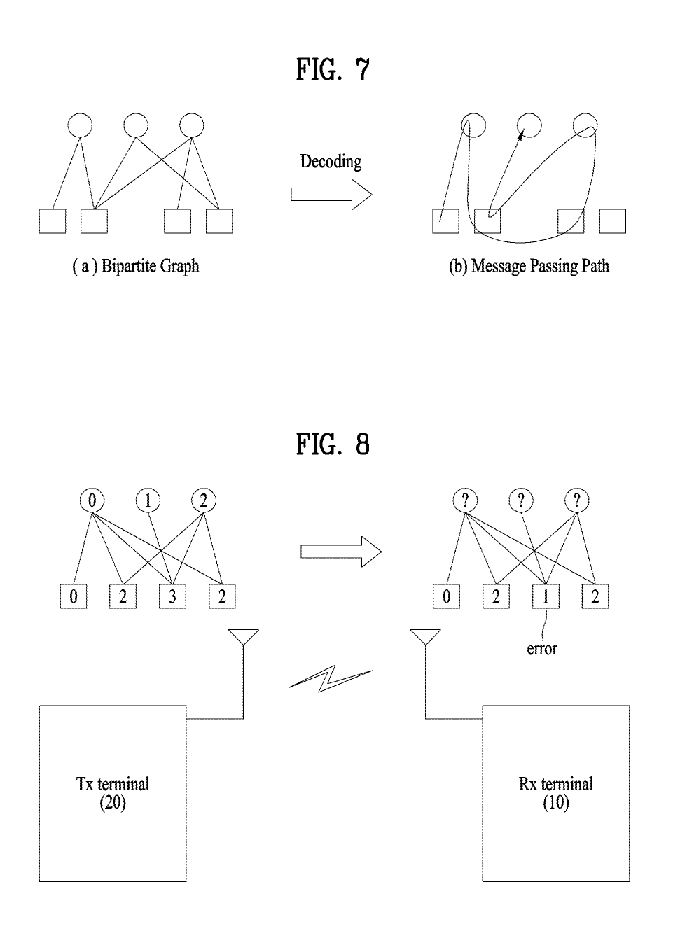

Referring to FIG. 6, the edges of R(3) and R(3) are excluded from the bipartite graph.

In addition, R(4) not used in the decoding is used for decoding, and R(5) is not used for decoding.

According to the decoding result, the reconstructed packets ‘0’, ‘1’, and ‘2’ are acquired as shown in FIG. 6. Since “VD(2) [symbol] VD(3)=VR(5)=3” of FIG. 6(f) is achieved, the Rx terminal may recognize the absence of errors in the reconstructed packet. In this way, the Rx terminal may perform error correction through the packet transmission path.

Meanwhile, assuming that errors are detected in the reconstructed packet acquired in FIG. 6(f), the Rx terminal may change the error packet candidate. In this case, the third Rx packet has already been excluded from the decoding process, such that the fifth Rx packet corresponding to R(5) having the degree of 2 may be determined to be the error packet candidate. The Rx terminal may exclude R(5) and the edge of R(5), and may re-perform decoding. The Rx terminal changes the error packet candidate and at the same time decoding is repeatedly performed until errors are not detected in the reconstructed packets. If errors are detected in the reconstructed packets although no more error packet candidates remain, the Rx terminal may determine that decoding has failed. If the decoding failure occurs, any one of the sets of the acquired reconstructed packets is randomly selected by previous decoding, such that the selected packet set may be supplied to an upper layer.

### D. Protocol Configured to Use the Checksum in Some Packets

As an example of the case in which the checksum is used in some packets, an exemplary case in which errors are detected through the checksum in the packet having the checksum will hereinafter be described.

Referring to FIG. 8, the Tx terminal may transmit the Tx packets [0, 2, 3, 2]. However, since errors occur in the third Tx packet, the Rx terminal may receive the Rx packets [0, 2, 1, 2]. In addition, the checksum is used in the third Rx packet, such that the Rx terminal detects the presence of errors in the third Rx packet.

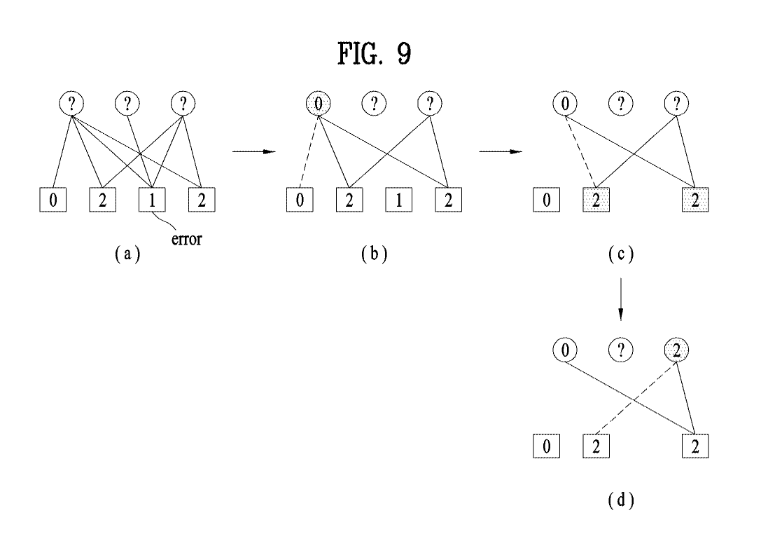

FIG. 9 is a conceptual diagram illustrating the decoding process based on the legacy MP algorithm. In accordance with the legacy ML algorithm, the third Rx packet has errors so that R(3) is discarded. The result obtained after R(3) is discarded and the decoding is performed is shown in FIG. 9(c). Since R(3) is discarded, the second reconstructed packet mapped to D(2) cannot be decoded as shown in FIG. 9(d). However, the correct decoding result can be obtained from the reconstructed packets of D(1) and D(3).

Assuming that multimedia data is used, a still image will be displayed on the part corresponding to the second reconstructed packet, such that more serious performance deterioration occurs as compared to the other case in which a display image having noise is output.

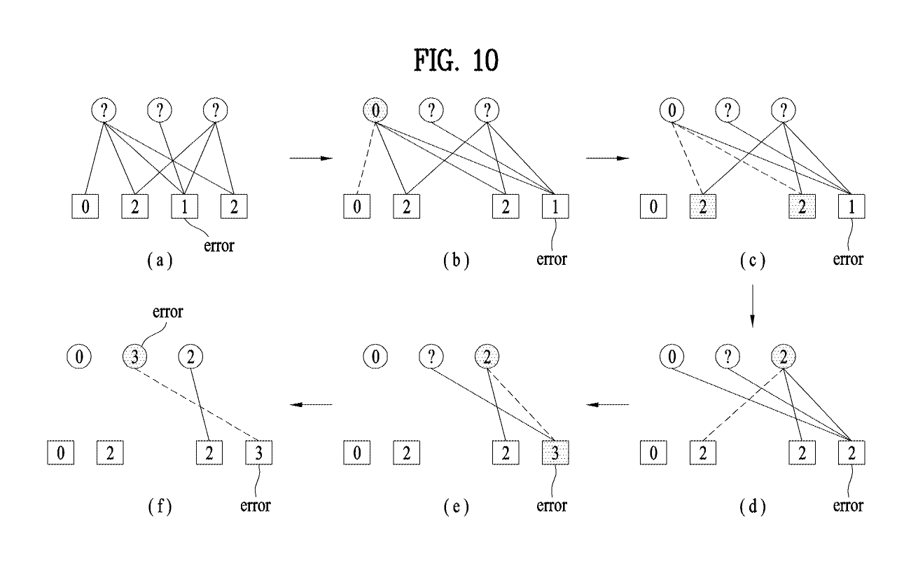

FIG. 10 is a conceptual diagram illustrating a decoding process based on the MP algorithm according to another embodiment. Instead of discarding the third Rx packet having errors and R(3), the Rx terminal may move R(3) to the last position as shown in FIG. 10(b). The resultant R(3) shifted to the last position will hereinafter be referred to as ‘R(3) for convenience of description.

Subsequently, the Rx terminal may schedule the packet transmission path to the exclusion of R(3), and may perform decoding. As illustrated in FIG. 10(d), the first and third reconstructed packets are obtained, and the second reconstructed packet is not acquired.

If a non-reconstructed packet exists, the Rx terminal may update the Rx packet of R(3) as shown in FIGS. 10(e) and 10(f), and may acquire VD(2) using the updated R(3) reception packet.

Subsequently, the reconstructed packets ‘0’, ‘3’, and ‘2’ are acquired according to the decoding result. When the reconstructed packets are compared with the input packets ‘0’, ‘1’, and ‘2’, although some noise is included in the second packet, the case of permitting some errors causing a noisy screen image is preferable to the other case of discarding the entire packet. In more detail, although the Rx packet includes one or more errors on a packet basis, this Rx packet includes normal symbols having no errors, such that the case of permitting some errors is considered more preferable.

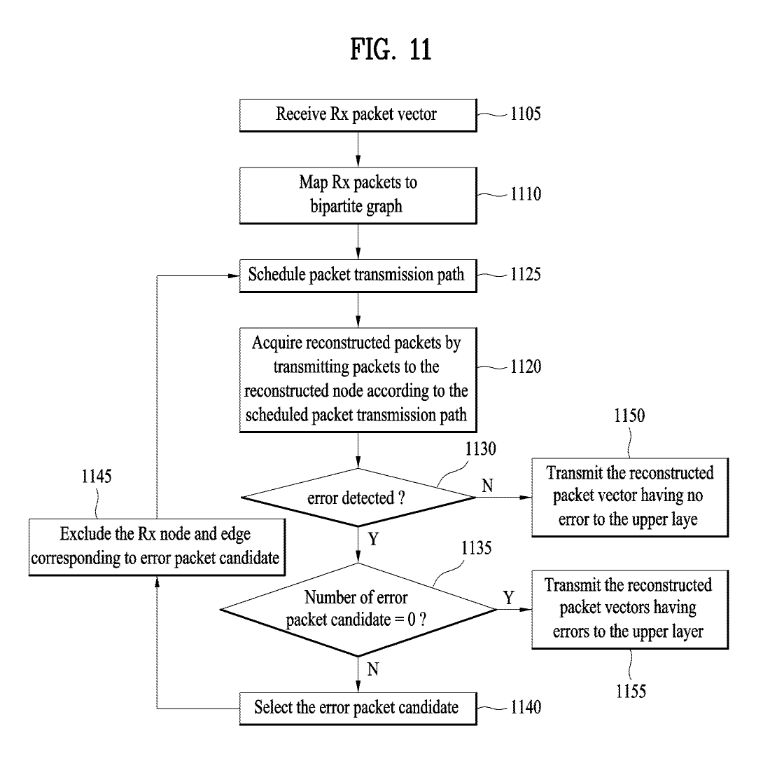

FIG. 11 is a flowchart illustrating a decoding method according to an embodiment of the present invention. The same content as in the above-mentioned embodiment will herein be omitted for convenience of description. It is assumed that the above-mentioned bipartite graph is prestored in the Rx terminal. However, according to another embodiment, the Rx terminal may receive information regarding the bipartite graph from the Tx terminal.

The Rx terminal may receive Rx packets from the Tx terminal in step 1105. The Rx terminal may map the Rx packets to the Rx nodes of the stored bipartite graph in step 1110.

The Rx terminal may schedule the first packet transmission path using the edges of the bipartite graph in step 1120. For example, through such scheduling, the Tx terminal may determine the transmission order of transmitting the Rx packets of the Rx nodes to the reconstructed node, and may determine the order of transmitting the reconstructed packet of the reconstructed node to the Rx nodes. Scheduling is a process for determining the packet transmission path such that the scheduling may be understood as a process for determining the order of elimination of plural edges. The Rx terminal may primarily transmit the Rx packet of the Rx node having the degree of 1 from among the plurality of Rx nodes to the reconstructed node. Preferably, the Rx node may schedule the shortest packet transmission path.

The Rx terminal may acquire the first reconstructed packets on the basis of the scheduled first packet transmission path in step 1125. For example, the Rx terminal may transmit the Rx packet of the first Rx node to the first reconstructed node through the first edge contained in the first packet transmission path. The Rx terminal may update the reconstructed packet of the first reconstructed node through the Rx packet transmitted through the first edge. The Rx terminal may transmit the updated reconstructed packet of the first reconstructed node to the second Rx node through the second edge. The first edge and the second edge are eliminated after transmission of the Rx packet and the reconstructed packet.

The Rx terminal may determine the presence or absence of errors in the first reconstructed packets in step 1130. For example, the Rx terminal may determine the presence or absence of errors in the first reconstructed packets using the Rx packets of the Rx nodes not located at the first packet transmission path.

If no errors are detected, the Rx terminal may transmit the first reconstructed packets having no errors to the upper layer in step 1150.

If errors are detected, the Rx terminal may determine whether the number of error packet candidate is set to zero ‘0’ in step 1135. For example, through repeated decoding, it is determined whether error packet candidates to be excluded are not present any more, or it is determined whether other error packet candidates are present. If each of all Rx packets has already been selected as such error packet candidate at least once, the number of error packet candidates becomes zero ‘0’.

If the number of error packet candidates is not zero, the Rx terminal may select a candidate of at least one error packet to be excluded from the Rx packets in step 1140. The Rx terminal may determine the candidate of the error packet on the basis of the number of edges connected to the Rx nodes. For example, this error packet candidate may include the Rx packet mapped to a node having a maximum number of connected edges from among Rx nodes, each of which has not been excluded. In addition, the Rx terminal may select the candidate of an error packet from among the Rx packets of the Rx nodes located at the first packet transmission path.

In the meantime, at least one Rx packet from among the Rx packets may be received through the UDP-Lite protocol without using the checksum. In this case, from among the plurality of Rx packets having the checksum, any one of the Rx packet having the checksum error and the other Rx packet having no checksum may be determined as the above error packet candidate.

The Rx terminal may exclude the Rx node mapped to the error packet candidate and the edge of the corresponding Rx node from the bipartite graph in step 1145, and may schedule the second packet transmission path in step 1120. The Rx terminal may acquire the second reconstructed packets according to the second packet transmission path in step 1125.

As described above, if one or more errors are detected in the second reconstructed packets in step 1130, the Rx terminal may recursively perform the above steps 1135, 1140, 1145, 1120, 1125, and 1130. As a result, the Rx terminal may re-determine the candidate of the error packet, and may re-acquire the reconstructed packets on the basis of the redetermined error packet candidate.

If one or more errors are detected in each of all the re-determined reconstructed packets, the Rx terminal may provide any one reconstructed packet set randomly selected from among the redetermined reconstructed packet sets to the upper layer in step 1155. For example, assuming that the process for obtaining the set of the reconstructed packets having no errors fails until all the error packet candidates are consumed, the reconstructed packet set having errors may be selected at random and then provided to the upper layer.

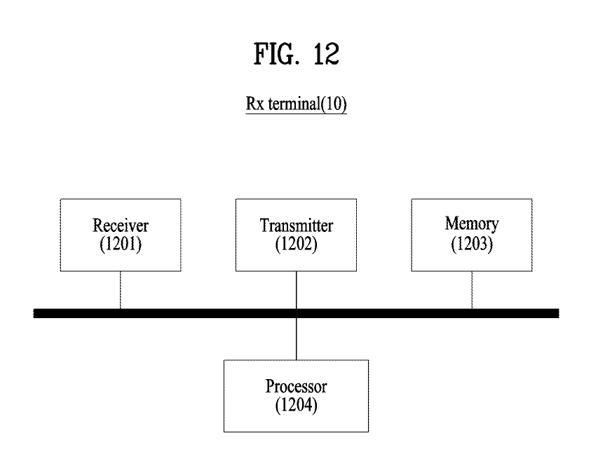

FIG. 12 is a block diagram illustrating an apparatus for performing the decoding method according to an embodiment of the present invention. The same elements as in the above-mentioned embodiments will not be described herein for clarity.

Referring to FIG. 12, the Rx terminal 10 may include a receiver 1201, a transmitter 1202, a memory 1203, and a processor 1204. However, not all the illustrated constituent elements are requisite for the Rx terminal 10. In addition, universal constituent elements not illustrated in the Rx terminal 10 may further be included as necessary.

The receiver 1201 may receive the Rx packets encoded by the LDPC code generation matrix.

The memory 1203 may store a bipartite graph corresponding to the LDPC code generation matrix and the Rx packets. In accordance with another embodiment, the memory 1203 may store only the LDPC code generation matrix, and the bipartite graph may also be generated from the LDPC code generation matrix stored in the memory 1203.

The processor 1204 may acquire the first reconstructed packets corresponding to the reconstructed nodes using the edges of the first packet transmission path in the bipartite graph. If one or more errors are detected in the first reconstructed packet, the processor 1204 may determine the candidate of the error packet to be excluded from the Rx packets. The processor 1204 may acquire the second reconstructed packets from the bipartite graph from which the determined error packet candidate is excluded. The processor 1204 may acquire the second reconstructed packets through the edges of the second packet transmission path from which the edge of the Rx node mapped to the error packet candidate is excluded.

The processor 1204 may determine the candidate of the error packet on the basis of the number of edges connected to the Rx nodes. The determined error packet candidate may be identical to the Rx packet mapped to a node having a maximum number of connected edges from among Rx nodes, each of which has not been excluded.

The processor 1204 may determine the presence or absence of errors in the first reconstructed packets using Rx packets of the Rx nodes not located at the first packet transmission path. The processor 1204 may select the candidate of an error packet from among the Rx packets of the Rx nodes located at the first packet transmission path.

The processor 1204 may transmit the Rx packet of the first Rx node to the first reconstructed node through the first edge of the first packet transmission path, so as to acquire the first reconstructed packets. The processor 1204 may update the reconstructed packet of the first reconstructed node through the Rx packet transmitted through the first edge. The processor 1204 may transmit the updated reconstructed packet of the first reconstructed node to the second Rx node through the second edge of the first packet transmission path. The first edge and the second edge are elimination after transmission of the Rx packet and the reconstructed packet.

If the error is detected in the second reconstructed packet, the processor 1204 may recursively perform the process for determining the error packet candidate and the process for acquiring the second reconstructed packet. The processor 1204 may re-determine the error packet candidate, and may re-acquire the second reconstructed packet on the basis of the redetermined error packet candidate. If one or more errors are detected in all the sets of the redetermined second reconstructed packets, the processor 1204 may provide the upper layer with one second reconstructed packet set having been randomly selected.

The receiver 1201 may receive at least one Rx packet from among the Rx packets through the UDP-Lite protocol without using the checksum. The processor 1204 may determine any one of the Rx packet having a checksum error from among the plurality of Rx packets having a checksum and the other Rx packet having no checksum to be the candidate of the error packet (i.e., error packet candidate).

The above-described embodiments of the present invention can be implemented by a variety of means, for example, hardware, firmware, software, or a combination thereof.

In the case of implementing the present invention by hardware, the present invention can be implemented with application specific integrated circuits (ASICs), Digital signal processors (DSPs), digital signal processing devices (DSPDs), programmable logic devices (PLDs), field programmable gate arrays (FPGAs), a processor, a controller, a microcontroller, a microprocessor, etc.

If operations or functions of the present invention are implemented by firmware or software, the present invention can be implemented in the form of a variety of formats, for example, modules, procedures, functions, etc. Software code may be stored in a memory to be driven by a processor. The memory may be located inside or outside of the processor, so that it can communicate with the aforementioned processor via a variety of well-known parts.

The detailed description of the exemplary embodiments of the present invention has been given to enable those skilled in the art to implement and practice the invention. Although the invention has been described with reference to the exemplary embodiments, those skilled in the art will appreciate that various modifications and variations can be made in the present invention without departing from the spirit or scope of the invention described in the appended claims. For example, those skilled in the art may use each construction described in the above embodiments in combination with each other. Accordingly, the invention should not be limited to the specific embodiments described herein, but should be accorded the broadest scope consistent with the principles and novel features disclosed herein.

Those skilled in the art will appreciate that the present invention may be carried out in other specific ways than those set forth herein without departing from the spirit and essential characteristics of the present invention. The above exemplary embodiments are therefore to be construed in all aspects as illustrative and not restrictive. The scope of the invention should be determined by the appended claims and their legal equivalents, not by the above description, and all changes coming within the meaning and equivalency range of the appended claims are intended to be embraced therein. Also, it will be obvious to those skilled in the art that claims that are not explicitly cited in the appended claims may be presented in combination as an exemplary embodiment of the present invention or included as a new claim by subsequent amendment after the application is filed.

### INDUSTRIAL APPLICABILITY

The embodiments of the present invention as described above are applicable to various mobile communication systems.

1. A method for decoding a low density parity check (LDPC) code for forward error correction (FEC) by a reception terminal of a wireless communication system, the method comprising:
in a bipartite graph including a plurality of nodes halved into reception nodes mapped to reception packets and reconstructed nodes connected to the reception nodes through edges, acquiring first reconstructed packets corresponding to the reconstructed nodes by using edges of a first packet transmission path;
if an error is detected in the first reconstructed packets, determining a candidate of an error packet to be excluded from the reception packet; and
acquiring second reconstructed packets from the bipartite graph from which the determined error packet candidate is excluded,
wherein the acquiring the second reconstructed packets includes
acquiring the second reconstructed packets through edges of a second packet transmission path from which an edge of a reception node mapped to the error packet candidate is excluded.

2. The method according to claim 1, wherein the determining the error packet candidate includes:
determining the error packet candidate based on a number of edges respectively connected to the reception nodes.

3. The method according to claim 2, wherein the determined error packet candidate corresponds to a reception packet having a maximum number of the connected edges from among a plurality of reception nodes not having history indicating that each reception node was excluded.

4. The method according to claim 1, wherein the determining the error packet candidate includes:
selecting the error packet candidate from among reception packets of reception nodes located at the first packet transmission path.

5. The method according to claim 1, further comprising:
determining whether an error is present in the first reconstructed packets, by using reception packets not located at the first packet transmission path.

6. The method according to claim 1, wherein the acquiring the first reconstructed packets includes:
transmitting a reception packet of a first reception node to a first reconstructed node through a first edge of the first packet transmission path;
updating a reconstructed packet of the first reconstructed node through the reception packet transmitted through the first edge; and
transmitting the updated reconstructed packet of the first reconstructed node to a second reception node through a second edge of the first path transmission path,
wherein the first edge and the second edge are eliminated after transmission of the reception packet and the reconstructed packet.

7. The method according to claim 1, wherein the edges of the bipartite graph respectively correspond to elements each having a value of 1 in the LDPC code generation matrix used to encode the reception packets

8. The method according to claim 1, wherein:
if an error is detected in the second reconstructed packets, the determining the error packet candidate and the acquiring the second reconstructed packets are recursively performed, such that the error packet candidate is re-determined and the second reconstructed packets are re-acquired based on the redetermined error packet candidate.

9. The method according to claim 8, further comprising:
if an error is detected in each of the redetermined second reconstructed packet sets because the determining the error packet candidate and the acquiring the second reconstructed packets are recursively performed,
providing one second reconstructed packet randomly selected from among the redetermined second reconstructed packets to an upper layer.

10. The method according to claim 1, wherein at least one reception packet from among the reception packets is received through a UDP-Lite protocol without having a checksum.

11. The method according to claim 10, wherein the determining the candidate of the error packet includes:
determining any one of a reception packet having a checksum error from among the reception packets having the checksum and a reception packet having no checksum to be the candidate of the error packet.

12. An apparatus for decoding a low density parity check (LDPC) code for forward error correction (FEC) of a wireless communication system, the apparatus comprising:
a receiver configured to receive encoded reception packets; and
a processor, in a bipartite graph including a plurality of nodes halved into reception nodes mapped to reception packets and reconstructed nodes connected to the reception nodes through edges, configured to acquire first reconstructed packets corresponding to the reconstructed nodes by using edges of a first packet transmission path, if an error is detected in the first reconstructed packets, to determine a candidate of an error packet to be excluded from the reception packet, and to acquire second reconstructed packets from the bipartite graph from which the determined error packet candidate is excluded,
wherein the processor is configured to acquire the second reconstructed packets through edges of a second packet transmission path from which an edge of a reception node mapped to the error packet candidate is excluded.

13. The apparatus according to claim 12, wherein:
the processor is configured to determine the error packet candidate based on a number of edges respectively connected to the reception nodes; and
the determined error packet candidate corresponds to a reception packet having a maximum number of the connected edges from among a plurality of reception nodes not having history indicating that each reception node was excluded.

14. The apparatus according to claim 12, wherein:
the processor determines whether an error is present in the first reconstructed packets, by using reception packets not located at the first packet transmission path, and selects the error packet candidate from among reception packets of the reception nodes located at the first packet transmission path.

15. The apparatus according to claim 12, wherein:
in order to acquire the first reconstructed packets, the processor transmits a reception packet of a first reception node to a first reconstructed node through a first edge of the first packet transmission path, updates a reconstructed packet of the first reconstructed node through the reception packet transmitted through the first edge, and transmits the updated reconstructed packet of the first reconstructed node to a second reception node through a second edge of the first path transmission path,
wherein the first edge and the second edge are eliminated after transmission of the reception packet and the reconstructed packet.

16. The apparatus according to claim 12, wherein:
if an error is detected in the second reconstructed packets, the processor recursively performs the determination of the error packet candidate and the acquisition of the second reconstructed packets, re-determines the error packet candidate, and re-acquire the second reconstructed packets based on the redetermined error packet candidate; and
if an error is detected in each of the redetermined second reconstructed packet sets because the determination of the error packet candidate and the acquisition of the second reconstructed packets are recursively performed, the processor provides one second reconstructed packet randomly selected from among the redetermined second reconstructed packets to an upper layer.

17. The apparatus according to claim 12, wherein:
the receiver is configured to receive at least one reception packet from among the reception packets through a UDP-Lite protocol without having a checksum; and
the processor is configured to determine any one of a reception packet having a checksum error from among the reception packets having the checksum and a reception packet having no checksum to be the candidate of the error packet.
